(19) United States
(12) Patent Application Publication
(10) Pub. No.: US 2018/0371618 A1
(43) Pub. Date: Dec. 27, 2018

(54) FILM HAVING PLATED-LAYER PRECURSOR LAYER, FILM HAVING PATTERNED PLATED LAYER, ELECTROCONDUCTIVE FILM, AND TOUCH PANEL

(71) Applicant: FUJIFILM Corporation, Tokyo (JP)

(72) Inventors: Takahiko ICHIKI, Kanagawa (JP); Naoki TSUKAMOTO, Kanagawa (JP); Takeshi SENGA, Kanagawa (JP); Takehiro KASAHARA, Kanagawa (JP); Yuko TERAO, Kanagawa (JP); Shuuji KANAYAMA, Kanagawa (JP)

(73) Assignee: FUJIFILM Corporation, Tokyo (JP)

(21) Appl. No.: 16/115,886

(22) Filed: Aug. 29, 2018

Related U.S. Application Data
(63) Continuation of application No. PCT/JP2017/008551, filed on Mar. 3, 2017.

(30) Foreign Application Priority Data
Mar. 11, 2016 (JP) 2016-048741

(51) Int. Cl. C23C 18/18; C23C 18/31; B32B 15/08; H05K 3/18; H05K 1/02; G06F 3/044

(52) U.S. Cl. CPC C23C 18/18; C23C 18/31; B32B 15/08; H05K 2203/072; H05K 1/0296; G06F 3/044; H05K 3/184

(57) ABSTRACT

An object of the present invention is to provide a film having a plated-layer precursor layer which is capable of forming a metal layer having excellent roll-to-roll productivity and excellent adhesiveness to a substrate. Another object of the present invention is to provide a film having a patterned plated layer as well as an electroconductive film and a touch panel using the same.

The film having a plated-layer precursor layer of the present invention is a film having a plated-layer precursor layer including a substrate, and an undercoat and a plated-layer precursor layer disposed on the substrate in this order from the substrate side, in which the undercoat has a hardness on the surface thereof of 10 N/mm² or less and a friction coefficient with release paper of 5 or less.

### CROSS-REFERENCE TO RELATED APPLICATIONS

This application is a Continuation of PCT International Application No. PCT/JP2017/008551 filed on Mar. 3, 2017, which claims priority under 35 U.S.C. § 119(a) to Japanese Patent Application No. 2016-048741 filed on Mar. 11, 2016. The above application is hereby expressly incorporated by reference, in its entirety, into the present application.

### BACKGROUND OF THE INVENTION

### 1. Field of the Invention

The present invention relates to a film having a plated-layer precursor layer, a film having a patterned plated layer, an electroconductive film, and a touch panel.

### 2. Description of the Related Art

An electroconductive film having a conductive film (electroconductive thin wire) disposed on a substrate has been used for various purposes. Particularly, in recent years, along with an increase in the rate at which a touch panel has been mounted on mobile phones or portable game devices, a demand for an electroconductive film for an electrostatic capacitance touch panel sensor capable of carrying out multi-point detection has been rapidly increasing.

For the formation of such a conductive film, for example, a method using a patterned plated layer has been proposed.

For example, JP2013-041942A discloses a “method for producing a laminate having a metal layer, including a step (1) of forming a primer layer on an inorganic substrate, using a composition for forming a primer layer containing a hydrolyzate obtained by hydrolyzing a silane coupling agent having at least one functional group selected from the group consisting of an epoxy group, an amino group, a vinyl group, a mercapto group, an acryloyloxy group, a phenyl group, and a cyano group under conditions of pH 1 to 8 and/or a condensate thereof, and a resin, a step (2) of forming a layer containing a polymer having a functional group capable of forming an interaction with a plating catalyst or a precursor thereof and a polymerizable group on the primer layer, and then applying energy to the layer containing the polymer to form a plated layer on the primer layer, a step (3) of applying a plating catalyst or a precursor thereof to the plated layer, and a step (4) of subjecting the plated layer to which the plating catalyst or the precursor thereof has been applied to a plating treatment, thereby forming a metal layer on the plated layer” as a method for forming a conductive film.

That is, in JP2013-041942A, first, a primer layer is formed on a substrate, and a plated-layer precursor layer containing a polymer having a functional group capable of forming an interaction with a plating catalyst or a precursor thereof and a polymerizable group is formed on the primer layer. Next, energy is applied to the plated layer precursor to form a patterned plated layer, and then a metal layer is provided on the patterned plated layer to form a conductive film.

Further, JP2013-041942A discloses that it is preferable to use an elastomer as a resin contained in the primer layer, from the viewpoint of further improving the adhesiveness of the metal layer.

### SUMMARY OF THE INVENTION

Meanwhile, in recent years, there has been a demand for improvement in productivity of a conductive film, and it is desired that the conductive film can be continuously produced through a roll-to-roll process using a film wound in a roll shape (hereinafter, referred to as “having excellent roll-to-roll productivity”).

The present inventors have studied a method of continuously producing a conductive film through a roll-to-roll process by a method using a patterned plated layer as in JP2013-041942A and then found that the film sometimes gets caught on the surface of a roll at the time of roll conveyance and therefore may not be conveyed in the case where an elastomer resin is used as the primer layer (hereinafter, also referred to as “undercoat”). In addition, it was found that this phenomenon is likely to occur particularly in the case of roll-conveying a film in which an undercoat formed of an elastomer is disposed on a substrate such that the undercoat is in contact with the roll.

On the other hand, along with demands for miniaturization and high performance of electronic equipment and electronic devices in recent years, thinning of wirings and narrowing of pitches in conductor circuits are progressing, and a further improvement in adhesiveness of the wiring to the substrate has also been constantly required. That is, it is also required to prevent a metal layer formed by depositing metal plating on the surface of the patterned plated layer from peeling from the substrate (hereinafter, referred to as “having excellent adhesiveness between the substrate and the metal layer”).

Accordingly, an object of the present invention is to provide a film having a plated-layer precursor layer which is capable of forming a metal layer having excellent roll-to-roll productivity and excellent adhesiveness to a substrate, and a film having a patterned plated layer.

Another object of the present invention is to provide an electroconductive film and a touch panel.

As a result of extensive studies to achieve the foregoing objects, the present inventors have found that the foregoing objects can be achieved in the case where the properties of the undercoat in the film having a plated-layer precursor layer are set such that the surface hardness is 10 N/mm² or less and the friction coefficient with release paper is 5 or less. The present invention has been completed based on these findings.

That is, the present inventors have found that the foregoing objects can be achieved by the following configurations.

(1) A film having a plated-layer precursor layer, comprising:

a substrate;

an undercoat disposed on the substrate; and

a plated-layer precursor layer disposed on the undercoat,

in which the undercoat has a hardness on the surface thereof of 10 N/mm² or less and a friction coefficient with release paper of 5 or less.

(2) The film having a plated-layer precursor layer according to (1), in which the plated-layer precursor layer contains a polymerization initiator and Compound X or Composition Y below.

Compound X: a compound having a functional group capable of interacting with a plating catalyst or a precursor thereof, and a polymerizable group

Composition Y: a composition containing a compound having a functional group capable of interacting with a plating catalyst or a precursor thereof, and a compound having a polymerizable group

(3) A film having a patterned plated layer, comprising:

a substrate;

an undercoat disposed on the substrate; and

a patterned plated layer disposed on the undercoat,

in which the undercoat has a hardness on the surface thereof of 10 N/mm² or less and a friction coefficient with release paper of 5 or less.

(4) An electroconductive film comprising:

the film having a patterned plated layer according to (3); and

a metal layer disposed on the patterned plated layer in the film having a patterned plated layer.

(5) The electroconductive film according to (4), in which the metal layer is formed by an electroless plating treatment.

(6) A touch panel comprising:

the electroconductive film according to (4) or (5).

According to the present invention, it is possible to provide a film having a plated-layer precursor layer which is capable of forming a metal layer having excellent roll-to-roll productivity and excellent adhesiveness to a substrate, and a film having a patterned plated layer.

Further, according to the present invention, it is possible to provide an electroconductive film and a touch panel.

### BRIEF DESCRIPTION OF THE DRAWINGS

FIG. 1 is a cross-sectional view schematically showing an example of an embodiment of a film having a plated-layer precursor layer of the present invention.

FIG. 2 is a cross-sectional view schematically showing an example of an embodiment of an electroconductive film of the present invention.

FIG. 3A is a cross-sectional view schematically showing an example of a step of curing a coating film 30 in a film 10 having a plated-layer precursor layer by exposure.

FIG. 3B is a cross-sectional view schematically showing an example of a step of obtaining a film 50 having a patterned plated layer.

FIG. 3C is a cross-sectional view schematically showing an example of a step of forming a metal layer 22 on a patterned plated layer 20 to obtain an electroconductive film 100.

### DESCRIPTION OF THE PREFERRED EMBODIMENTS

Hereinafter, the present invention will be described in detail.

Descriptions of the constituent features described below are sometimes made based on representative embodiments of the present invention, but the present invention is not limited to such embodiments.

Further, in the present specification, the numerical range expressed by using “to” means a range including numerical values described before and after “to” as a lower limit value and an upper limit value, respectively.

Further, in the present specification, the term “actinic rays” or “radiation” includes, for example, a bright line spectrum of a mercury lamp, far ultraviolet rays typified by an excimer laser, extreme ultraviolet rays (EUV light), X-rays, and electron beams (EB). In the present invention, the light means actinic rays or radiation.

Further, in the present specification, unless otherwise specified, the term “exposure” includes not only exposure by a mercury lamp, far ultraviolet rays typified by an excimer laser, extreme ultraviolet rays, X-rays and EUV light, but also lithography by electron beams, and particle beams such as ion beams.

[Film Having a Plated-Layer Precursor Layer]

A film substrate having a plated-layer precursor layer of the present invention includes a substrate, an undercoat disposed on the substrate, and a plated-layer precursor layer disposed on the undercoat,

in which the undercoat has a hardness on the surface thereof (hereinafter, also referred to as “surface hardness”) of 10 N/mm² or less and a friction coefficient with release paper of 5 or less.

The surface hardness of the undercoat is determined as a universal hardness (N/mm²) by the following measurement method.

(Surface Hardness)

A spherical indenter having a tip radius of curvature of 0.2 mm is brought into contact with the surface of the undercoat (film thickness 2 μm) using an HM 500 type film hardness tester manufactured by Fisher Instruments Co., Ltd., and a universal hardness (N/Mm²) is measured under the conditions of a maximum load of 2 mN and a loading time of 10 sec.

The “friction coefficient” of the undercoat is determined by the following measurement method.

(Friction Coefficient)

The release paper is placed without applying a force such that the release surface of the release paper is brought into contact with the surface of the undercoat. Next, the load applied in the case where a 100 g weight is placed thereon and the release paper is moved at a speed of 100 mm/min in the horizontal direction is measured using a force gauge FGX-2 (manufactured by Nidec-Shimpo Corporation).

The friction coefficient is obtained by dividing the obtained measured value (load) by the weight of the weight.

In the evaluation test of the friction coefficient, CERAPHYL 38BKE (manufactured by Toray Industries, Inc.) was used as the “release paper”.

In the case where the film having a plated-layer precursor layer of the present invention is made to have the above-mentioned configuration, it is possible to form a metal layer having excellent roll-to-roll productivity and excellent adhesiveness to a substrate.

Although the reason that such excellent properties are achieved is not clear in detail, it is presumed as follows.

The feature of the film having a plated-layer precursor layer of the present invention is that the physical property value of the undercoat is such that the surface hardness is 10 N/mm² or less and the friction coefficient with release paper is 5 or less.

The present inventors presume that the reason that it is difficult to convey a film using an elastomer resin as an undercoat as disclosed in JP2013-041942A by a roll is that the undercoat deforms in the case where it comes into contact with the roll and then stops the rotation of the roll. This phenomenon is likely to occur particularly in the case where a film on which an undercoat formed from an elastomer is disposed on a substrate is roll-conveyed such that the undercoat is in contact with the roll. Even in the case where the film, on which the plated-layer precursor layer is further formed on the undercoat of the film, is roll-conveyed such that the plated-layer precursor layer is in contact with the roll, the above-mentioned conveyance failure is likely to occur in the case where the film thickness of the plated-layer precursor layer is thin. This is considered to be because, in the case where the film thickness of the plated-layer precursor layer is thin, the plated-layer precursor layer is easily influenced by the physical properties of the undercoat which is an underlayer.

On the other hand, a metal layer is formed on the undercoat through a patterned plated layer. Therefore, in the case where the undercoat is formed of a rigid material which is difficult to be deformed upon contact with the roll, it is difficult to alleviate the stress generated at the time of formation of the patterned plated layer and the metal layer, and the interface between the patterned plated layer and the undercoat and the interface between the patterned plated layer and the metal layer tend to peel off easily. In other words, bringing the metal layer into good contact with the substrate is considered difficult.

As a result of various studies based on the above findings, the present inventors have found that, in the case where the physical property values of the undercoat are set such that the surface hardness is 10 N/mm² or less and the friction coefficient with release paper is 5 or less, the undercoat is not deformed even in the case of being in contact with the roll, and the adhesiveness of the metal layer is excellent.

Hereinafter, first, the configuration of the film having a plated-layer precursor layer of the present invention will be described in detail.

The film having a plated-layer precursor layer of the present invention has a substrate, an undercoat disposed on the substrate, and a plated-layer precursor layer disposed on the undercoat.

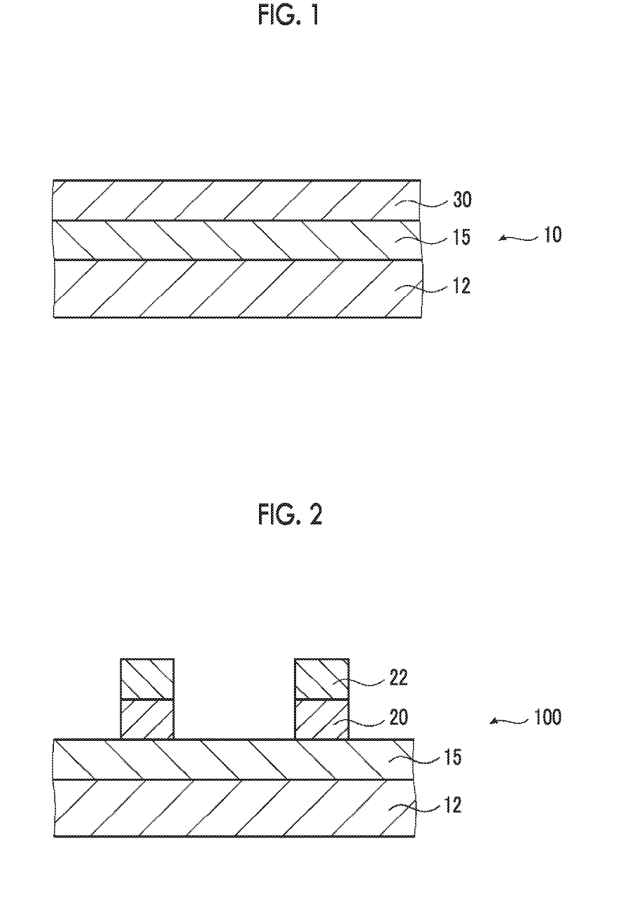

FIG. 1 is a schematic cross-sectional view showing an example of an embodiment of a film having a plated-layer precursor layer of the present invention. A film 10 having a plated-layer precursor layer of FIG. 1 includes a substrate 12, an undercoat 15 disposed on the substrate 12, and a plated-layer precursor layer 30 disposed on the undercoat 15.

Although FIG. 1 shows a configuration in which the undercoat 15 and the plated-layer precursor layer 30 are provided only on one surface of the substrate 12, the film having a plated-layer precursor layer of the present invention may be a configuration in which the undercoat 15 and the plated-layer precursor layer 30 are provided on both surfaces of the substrate 12.

Hereinafter, the substrate, the undercoat, and the plated-layer precursor layer constituting the film having a plated-layer precursor layer of the present invention will be described in detail.

<Substrate>

The substrate is not particularly limited as long as it has two principal surfaces and supports a patterned plated layer to be described later. The substrate is preferably an insulating substrate, more specific examples of which include a resin substrate, a ceramic substrate, and a glass substrate.

Examples of the material of the resin substrate include a polyether sulfone-based resin, a poly(meth)acrylic resin, a polyurethane-based resin, a polyester-based resin (for example, polyethylene terephthalate or polyethylene naphthalate), a polycarbonate-based resin, a polysulfone-based resin, a polyamide-based resin, a polyarylate-based resin, a polyolefin-based resin, a cellulose-based resin, a polyvinyl chloride-based resin, and a cycloolefin-based resin. Among them, a polyester-based resin (for example, polyethylene terephthalate or polyethylene naphthalate) or a polyolefin-based resin is preferable. The poly(meth)acrylic resin means a polyacrylic resin or a polymethacrylic resin.

The thickness (mm) of the substrate is not particularly limited, but it is preferably 0.01 to 2 mm and more preferably 0.02 to 0.1 mm from the viewpoint of the balance of handleability and thickness reduction.

Further, it is preferred that the substrate properly transmits light. Specifically, the total light transmittance of the substrate is preferably 85% to 100%.

Further, the substrate may have a multilayer structure. For example, a functional film may be included as one of the layers. Moreover, the substrate itself may be a functional film. Examples of the functional film include, but are not particularly limited to, a polarizing plate, a phase difference film, a cover plastic, a hard coat film, a barrier film, a pressure sensitive film, an electromagnetic wave shielding film, a heat generating film, an antenna film, and a wiring film for a device other than a touch panel.

Specific examples of the functional film used for a liquid crystal cell particularly associated with a touch panel include a polarizing plate such as NPF series (manufactured by Nitto Denko Corporation) or HLC2 series (manufactured by Sanritz Corporation); a phase difference film such as a WV film (manufactured by Fujifilm Corporation); a cover plastic such as FAINDE (manufactured by Dai Nippon Printing Co., Ltd.), TECHNOLOGY (manufactured by Sumitomo Chemical Co., Ltd.), IUPILON (manufactured by Mitsubishi Gas Chemical Company), SILPLUS (manufactured by Nippon Steel & Sumikin Chemical Co., Ltd.), ORGA (manufactured by Nippon Synthetic Chemical Industry Co., Ltd.), or SHORAYAL (manufactured by Showa Denko K.K.); and a hard coat film such as H series (manufactured by Lintec Corporation), FHC series (manufactured by Higashiyama Film Co., Ltd.), or a KB film (manufactured by Kimoto Co., Ltd.). These may form a patterned plated layer on the surface of each functional film.

Further, cellulose triacetate may be occasionally used for a polarizing plate or a phase difference film as described in JP2007-26426A. Among them, from the viewpoint of resistance to a plating process, a cycloolefin (co)polymer can be used in place of cellulose triacetate. For example, ZEONOR (manufactured by Zeon Corporation) or the like may be exemplified.

<Undercoat>

The thickness of the undercoat is not particularly limited, but it is generally preferably 0.01 to 100 μm, more preferably 0.05 to 20 m, and still more preferably 0.05 to 10 μm.

The surface hardness of the undercoat is 10 N/mm² or less, preferably 8 N/mm² or less, and more preferably 5 N/mm² or less. The surface hardness of the undercoat can be obtained by the above-mentioned method.

The undercoat has a friction coefficient with release paper of 5 or less, preferably 3 or less, and more preferably 1 or less. The friction coefficient between the undercoat and the release paper can be obtained by the above-mentioned method.

By setting the surface hardness of the undercoat and the friction coefficient of the undercoat with release paper to the above-specified numerical ranges, a film having a plated-layer precursor layer capable of forming a metal layer having excellent roll-to-roll productivity and excellent adhesiveness to the substrate can be obtained.

The material of the undercoat is not particularly limited as long as the surface hardness and the friction coefficient with release paper are within a predetermined range, but it is preferable to include a urethane resin. The urethane resin may be, for example, a reaction product of a diol compound and a diisocyanate compound.

Examples of the diol compound include diols such as ethylene glycol, propylene glycol, 1,2-propanediol, 1,3-propanediol, 1,3-butanediol, 1,4-butanediol, neopentyl glycol, 1,5-pentanediol, 1,6-hexanediol, 3-methylpentanediol, diethylene glycol, 1,4-cyclohexanedimethanol, 3-methyl-1,5-pentanediol, 2-methyl-1,3-propanediol, 2,2-diethyl-1,3-propanediol, 2-butyl-2-ethyl-1,3-propanediol, xylylene glycol, hydrogenated bisphenol A or bisphenol A, and polyalkylene glycol. Also, alkylene oxide adducts of these compounds (for example, an ethylene oxide adduct and a propylene oxide adduct) can be mentioned.

Among them, polyalkylene glycol is preferable and polyethylene glycol, polypropylene glycol, or polytetramethylene glycol is more preferable, from the viewpoint of easily adjusting the surface hardness and the friction coefficient with release paper in a predetermined range. The average addition molar number of the oxyalkylene in the polyalkylene glycol is preferably 3 to 20. The weight-average molecular weight of the polyalkylene glycol is preferably 100 to 2,000.

The diol compounds may be used alone or in combination of two or more thereof.

Examples of the diisocyanate compound include an aromatic diisocyanate compound such as 2,4-tolylene diisocyanate, a dimer of 2,4-tolylene diisocyanate, 2,6-tolylene diisocyanate, p-xylylene diisocyanate, m-xylylene diisocyanate, 4,4′-diphenylmethane diisocyanate, 1,5-naphthylene diisocyanate, or 3,3′-dimethylbiphenyl-4,4′-diisocyanate; an aliphatic diisocyanate compound such as hexamethylene diisocyanate, trimethylhexamethylene diisocyanate, lysine diisocyanate, or dimer acid diisocyanate; and an alicyclic diisocyanate compound such as isophorone diisocyanate, 4,4′-methylene bis(cyclohexylisocyanate), methylcyclohexane-2,4 (or 2,6)diisocyanate, or 1,3-(isocyanatomethyl)cyclohexane. Among these, an aliphatic diisocyanate compound such as isophorone diisocyanate or hexamethane diisocyanate is preferable from the viewpoint of high transparency of the cured product.

The diisocyanate compounds may be used alone or in combination of two or more thereof.

The urethane resin is synthesized, for example, by adding and heating the diisocyanate compound and the diol compound, and a known catalyst in an aprotic solvent. The molar ratio of the diisocyanate and diol compounds used in the synthesis is not particularly limited and may be appropriately selected depending on the purpose. It is preferably 1:1.2 to 1.2:1.

A photocurable material may be used as the urethane resin. As the photocurable urethane resin, it is preferable to use a urethane (meth)acrylate synthesized from a diisocyanate compound, a diol compound, and a hydroxyalkyl (meth)acrylate. Among them, from the viewpoint of easily adjusting the surface hardness and the friction coefficient with release paper in a predetermined range, preferred is urethane di(meth)acrylate, and particularly preferred is a urethane di(meth)acrylate oligomer having a weight-average molecular weight range to be described later.

The (meth)acrylate means acrylate or methacrylate. Examples of the diisocyanate compound and the diol compound include the above-mentioned compounds, and preferred aspects thereof are also the same.

Examples of the hydroxyalkyl (meth)acrylate include hydroxyl group-containing (meth)acrylate such as hydroxyethyl (meth)acrylate (for example, 2-hydroxyethyl (meth)acrylate), hydroxypropyl (meth)acrylate (for example, 2-hydroxypropyl (meth)acrylate), hydroxybutyl (meth)acrylate (for example, 2-hydroxybutyl (meth)acrylate), 4-hydroxybutyl (meth)acrylate), hydroxyhexyl (meth)acrylate (for example, 6-hydroxyhexyl (meth)acrylate), or pentaerythritol tri(meth)acrylate; a hydroxyl group-containing (meth)acrylate-modified product represented by a caprolactone-modified product or alkyl oxide-modified product thereof; and an addition reaction product of a monoepoxy compound such as butyl glycidyl ether, 2-ethylhexyl glycidyl ether, or glycidyl (meth)acrylate with (meth)acrylic acid. Among them, hydroxyethyl (meth)acrylate or hydroxybutyl (meth)acrylate is preferable from the viewpoint of easily adjusting the surface hardness and the friction coefficient with release paper in a predetermined range.

The hydroxyalkyl (meth)acrylates may be used alone or in combination of two or more thereof.

In addition, in the case of synthesizing urethane (meth)acrylate, a component (for example, a reactive diluted monomer) other than the foregoing components may be further contained as a raw material component.

Examples of the reactive diluted monomer include an alicyclic (meth)acrylate such as isobornyl (meth)acrylate or cyclohexyl (meth)acrylate; and an aromatic (meth)acrylate such as phenoxyethyl (meth)acrylate.

The reactive diluted monomers may be used alone or in combination of two or more thereof.

The urethane (meth)acrylate can be produced by a known method. For example, the urethane (meth)acrylate can be synthesized in such a manner that a diol compound is added to a diisocyanate compound, the mixture is reacted at 50° C. to 80° C. for about 3 to 10 hours, a hydroxyalkyl (meth)acrylate, an optional reactive diluted monomer, a catalyst such as dibutyltin dilaurate, and a polymerization inhibitor such as methylhydroquinone are added thereto, and the mixture is further reacted at 60° C. to 70° C. for 3 to 12 hours.

The ratio of the diisocyanate compound, the diol compound, and the hydroxyalkyl (meth)acrylate used is not particularly limited as long as the desired surface hardness and friction coefficient with release paper are achieved, but it is preferable such that 0.9≤(total number of isocyanate groups in diisocyanate compound)/(total number of hydroxyl groups in diol compound and hydroxyalkyl (meth)acrylate)≤1.1.

(Weight-Average Molecular Weight)

From the viewpoint of easily adjusting the surface hardness and the friction coefficient with release paper in a predetermined range, the weight-average molecular weight of the urethane (meth)acrylate is preferably 5,000 or more and 120,000 or less, more preferably 15,000 or more and 80,000 or less, and still more preferably 30,000 or more and 70,000 or less in terms of polystyrene measured by a gel permeation chromatography (GPC) method.

The GPC method is based on a method using HLC-8020 GPC (manufactured by Tosoh Corporation) and using TSKgel Super HZM-H, TSKgel Super HZ4000, and TSKgel Super HZ2000 (manufactured by Tosoh Corporation, 4.6 mm ID×15 cm) as columns and tetrahydrofuran (THF) as an eluent.

The undercoat may contain other additives (for example, a sensitizer, an antioxidant, an antistatic agent, an ultraviolet absorber, a filler, a particle, a flame retardant, a surfactant, a lubricant, and a plasticizer).

<Method of Forming Undercoat>

The method of forming an undercoat on a substrate is not particularly limited and examples thereof include a method in which a composition containing the above-mentioned urethane resin and various components optionally added is applied onto a substrate to form an undercoat (coating method), and a method in which an undercoat is formed on a temporary substrate and is then transferred to the substrate surface (transfer method). Among them, a coating method is preferable from the viewpoint of easily controlling the thickness.

Hereinafter, aspects of the coating method will be described in detail.

The composition used in the coating method preferably contains at least various additives in addition to the urethane resin described above. In the case where the urethane resin contains a polymerizable group (for example, an ethylenically unsaturated group) in the structure thereof, it is preferred that the composition contains a polymerization initiator. The content of the polymerization initiator in the composition is not particularly limited, but from the viewpoint of the curability of the undercoat, it is preferably 0.01% to 5% by mass and more preferably 0.1% to 3% by mass with respect to the total mass of the composition. As the polymerization initiator, those exemplified in the description of the plated-layer precursor layer to be described later can be used.

In addition, the composition preferably contains a solvent from the viewpoint of handleability. Examples of the solvent that can be used include, but are not particularly limited to, water; an alcohol-based solvent such as methanol, ethanol, propanol, ethylene glycol, l-methoxy-2-propanol, glycerin, or propylene glycol monomethyl ether, an acid such as acetic acid; a ketone-based solvent such as acetone, methyl ethyl ketone, or cyclohexanone; an amide-based solvent such as formamide, dimethylacetamide, or N-methylpyrrolidone; a nitrile-based solvent such as acetonitrile or propionitrile; an ester-based solvent such as methyl acetate and ethyl acetate; a carbonate-based solvent such as dimethyl carbonate or diethyl carbonate; additionally an ether-based solvent, a glycol-based solvent, an amine-based solvent, a thiol-based solvent, and a halogen-based solvent.

Among them, an alcohol-based solvent, an amide-based solvent, a ketone-based solvent, a nitrile-based solvent, or a carbonate-based solvent is preferable.

The content of the solvent in the composition is not particularly limited, but it is preferably 50% to 98% by mass and more preferably 60% to 95% by mass, with respect to the total amount of the composition. In the case where the content of the solvent is within the above-specified range, handleability of the composition is excellent, and control of the layer thickness is easy.

In the case of the coating method, the method of applying the composition onto the substrate is not particularly limited, and a known method (for example, a spin coating method, a die coating method, or a dip coating method) can be used.

In the case where the undercoat is disposed on both surfaces of the substrate, the composition may be applied to each surface of the substrate one by one, or the substrate may be immersed in the composition so that the composition is applied to both surfaces of the substrate at once.

From the viewpoint of handleability and production efficiency, an aspect of forming a coating film by applying the composition onto a substrate, and performing a drying treatment as necessary to remove the remaining solvent is preferable.

The conditions of the drying treatment are not particularly limited, but from the viewpoint of excellent productivity, it is preferable to carry out the drying treatment at room temperature to 220° C. (preferably 50° C. to 120° C.) for 1 to 30 minutes (preferably 1 to 10 minutes).

In the case where the coating film of the undercoat is formed of a urethane resin containing a polymerizable group, exposure is preferably carried out. The method of exposure is not particularly limited and may be, for example, a method of irradiating actinic rays or radiation. For irradiation with actinic rays, an ultraviolet (UV) lamp, light irradiation by visible light, or the like is used. Examples of the light source include a mercury lamp, a metal halide lamp, a xenon lamp, a chemical lamp, and a carbon arc lamp. Examples of the radiation include electron beams, X-rays, ion beams, and far infrared rays. By exposing the coating film, the polymerizable group contained in the compound in the coating film is activated, crosslinking occurs between the compounds, and the curing of the layer progresses. The exposure energy may be about 10 to 8,000 mJ/cm² and is preferably in the range of 50 to 3,000 mJ/cm².

<Plated-Layer Precursor Layer>

The plated-layer precursor layer is a layer which becomes a patterned plated layer by being cured into a pattern by exposure to be described hereinafter and preferably contains at least a polymerization initiator and Compound X or Composition Y below. More specifically, the plated-layer precursor layer may be a layer containing a polymerization initiator and Compound X, or a layer containing a polymerization initiator and Composition Y.

Compound X: a compound having a functional group capable of interacting with a plating catalyst or a precursor thereof (hereinafter, simply referred to also as an “interactive group”), and a polymerizable group

Composition Y: a composition containing a compound having a functional group capable of interacting with a plating catalyst or a precursor thereof, and a compound having a polymerizable group

Hereinafter, first, materials contained in the plated-layer precursor layer will be described in detail.

(Polymerization Initiator)

The polymerization initiator is not particularly limited, and a known polymerization initiator (so-called photopolymerization initiator) or the like can be used. Examples of the polymerization initiator include benzophenones, acetophenones, α-aminoalkylphenones, benzoins, ketones, thioxanthones, benzyls, benzyl ketals, oxime esters, anthrones, tetramethylthiuram monosulfides, bisacylphosphine oxides, acylphosphine oxides, anthraquinones, azo compounds, and derivatives thereof.

The content of the polymerization initiator in the plated-layer precursor layer is not particularly limited, but from the viewpoint of the curability of the plated layer, it is preferably 0.01% to 5% by mass and more preferably 0.1% to 3% by mass with respect to the total mass of the plated-layer precursor layer.

(Compound X)

Compound X is a compound having an interactive group and a polymerizable group.

The interactive group is intended to refer to a functional group capable of interacting with a plating catalyst or a precursor thereof which is applied to a patterned plated layer. For example, a functional group capable of forming an electrostatic interaction with a plating catalyst or a precursor thereof, or a nitrogen-, sulfur- or oxygen-containing functional group capable of coordinating with a plating catalyst or a precursor thereof may be used.

More specific examples of the interactive group include nitrogen-containing functional groups such as an amino group, an amide group, an imido group, a urea group, a tertiary amino group, an ammonium group, an amidino group, a triazine ring, a triazole ring, a benzotriazole group, an imidazole group, a benzimidazole group, a quinoline group, a pyridine group, a pyrimidine group, a pyrazine group, a nazoline group, a quinoxaline group, a purine group, a triazine group, a piperidine group, a piperazine group, a pyrrolidine group, a pyrazole group, an aniline group, a group containing an alkylamine structure, a group containing an isocyanuric structure, a nitro group, a nitroso group, an azo group, a diazo group, an azide group, a cyano group, and a cyanate group; oxygen-containing functional groups such as an ether group, a hydroxyl group, a phenolic hydroxyl group, a carboxylic acid group, a carbonate group, a carbonyl group, an ester group, a group containing an N-oxide structure, a group containing an S-oxide structure, and a group containing an N-hydroxy structure; sulfur-containing functional groups such as a thiophene group, a thiol group, a thiourea group, a thiocyanurate group, a benzothiazole group, a mercaptotriazine group, a thioether group, a thioxy group, a sulfoxide group, a sulfone group, a sulfite group, a group containing a sulfoximine structure, a group containing a sulfoxonium salt structure, a sulfonate group, and a group containing a sulfonic ester structure; phosphorus-containing functional groups such as a phosphate group, a phosphoramide group, a phosphine group, and a group containing a phosphoric ester structure; and groups containing halogen atoms such as a chlorine atom and a bromine atom. In a functional group that may have a salt structure, a salt thereof may also be used.

Among them, preferred is an ionic polar group such as a carboxylic acid group, a sulfonate group, a phosphate group, or a boronate group, an ether group, or a cyano group, and more preferred is a carboxylic acid group (carboxyl group) or a cyano group, from the viewpoint of high polarity and high adsorptive capacity to a plating catalyst or a precursor thereof.

Compound X may contain two or more types of interactive groups.

The polymerizable group is a functional group capable of forming a chemical bond through the application of energy, and examples thereof include a radically polymerizable group and a cationic polymerizable group. Among them, a radically polymerizable group is preferable from the viewpoint of superior reactivity. Examples of the radically polymerizable group include unsaturated carboxylic ester groups such as an acrylic ester group (acryloyloxy group), methacrylic ester group (methacryloyloxy group), an itaconic ester group, a crotonic ester group, an isocrotonic ester group, and a maleic ester group; additionally a styryl group, a vinyl group, an acrylamide group, and an methacrylamide group. Among them, a methacryloyloxy group, an acryloyloxy group, a vinyl group, a styryl group, an acrylamide group, or methacrylamide group is preferred and a methacryloyloxy group, an acryloyloxy group, or a styryl group is more preferred.

Compound X may contain two or more polymerizable groups. The number of the polymerizable groups contained in Compound X is not particularly limited and may be one or two or more.

Compound X may be a low molecular weight compound or a high molecular weight compound. The low molecular weight compound is intended to refer to a compound having a molecular weight of less than 1,000, and the high molecular weight compound is intended to refer to a compound having a molecular weight of 1,000 or more.

Further, the low molecular weight compound having a polymerizable group corresponds to a so-called monomer. Further, the high molecular weight may be a polymer having a predetermined repeating unit.

Further, the compounds may be used alone or in combination of two or more thereof.

In the case where Compound X is a polymer, the weight-average molecular weight of the polymer is not particularly limited and is preferably 1,000 or more and 700,000 or less and more preferably 2,000 or more and 200,000 or less, from the viewpoint of superior handleability such as solubility. In particular, the weight-average molecular weight is more preferably 20,000 or more from the viewpoint of polymerization sensitivity.

The method of synthesizing such a polymer having a polymerizable group and an interactive group is not particularly limited and a known synthesis method (see paragraphs [0097] to [0125] of JP2009-280905A) is used.

<<Suitable Aspect 1 of Polymer>>

A first preferred aspect of the polymer may be, for example, a copolymer containing a polymerizable group-containing repeating unit represented by Formula (a) (hereinafter, also referred to as a “polymerizable group unit” where appropriate) and an interactive group-containing repeating unit represented by Formula (b) (hereinafter, also referred to as an “interactive group unit” where appropriate).

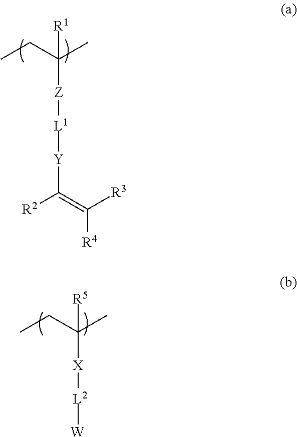

In Formula (a) and Formula (b), R¹ to R⁵ each independently represent a hydrogen atom, or a substituted or unsubstituted alkyl group (for example, a methyl group, an ethyl group, a propyl group, or a butyl group). Further, the type of the substituent is not particularly limited, and examples thereof include a methoxy group, a chlorine atom, a bromine atom, and a fluorine atom.

R¹ is preferably a hydrogen atom, a methyl group, or a methyl group substituted with a bromine atom. R² is preferably a hydrogen atom, a methyl group, or a methyl group substituted with a bromine atom. R³ is preferably a hydrogen atom. R⁴ is preferably a hydrogen atom. R⁵ is preferably a hydrogen atom, a methyl group, or a methyl group substituted with a bromine atom.

In Formula (a) and Formula (b), X, Y, and Z each independently represent a single bond, or a substituted or unsubstituted divalent organic group. Examples of the divalent organic group include a substituted or unsubstituted divalent aliphatic hydrocarbon group (which preferably has 1 to 8 carbon atoms. For example, an alkylene group such as a methylene group, an ethylene group, or a propylene group), a substituted or unsubstituted divalent aromatic hydrocarbon group (which preferably has 6 to 12 carbon atoms. For example, a phenylene group), —O—, —S—, —SO₂—, —N(R)— (R: alkyl group), —CO—, —NH—, —COO—, —CONH—, and a group formed by combining these groups (for example, an alkyleneoxy group, an alkyleneoxycarbonyl group, or an alkylenecarbonyloxy group).

X, Y, and Z are each preferably a single bond, an ester group (—COO—), an amide group (—CONH—), an ether group (—O—), or a substituted or unsubstituted divalent aromatic hydrocarbon group and more preferably a single bond, an ester group (—COO—), or an amide group (—CONH—), from the viewpoint of easy polymer synthesis and superior adhesiveness of a metal layer.

In Formula (a) and Formula (b), L¹ and L² each independently represent a single bond, or a substituted or unsubstituted divalent organic group. The divalent organic group has the same definition as in the divalent organic group described for X, Y, and Z above.

L¹ is preferably an aliphatic hydrocarbon group or a divalent organic group (for example, an aliphatic hydrocarbon group) having a urethane bond or a urea bond from the viewpoint of easy polymer synthesis and superior adhesiveness of a metal layer. Among them, preferred are groups having a total number of carbon atoms of 1 to 9. The total number of carbon atoms in L¹ refers to the total number of carbon atoms contained in the substituted or unsubstituted divalent organic group represented by L¹.

Further, L² is preferably a single bond, a divalent aliphatic hydrocarbon group, a divalent aromatic hydrocarbon group, or a group formed by combining these groups, from the viewpoint of superior adhesiveness of a metal layer. Among them, L² is more preferably a single bond or has a total number of carbon atoms of 1 to 15. The divalent organic group is preferably unsubstituted. Here, the total number of carbon atoms in L² refers to a total number of carbon atoms contained in the substituted or unsubstituted divalent organic group represented by L².

In Formula (b), W represents an interactive group. The definition of the interactive group is as described above.

The content of the polymerizable group unit is preferably 5 to 50 mol % and more preferably 5 to 40 mol % with respect to the total repeating units in the polymer, from the viewpoint of reactivity (curability and polymerizability) and inhibition of gelation during synthesis.

Further, the content of the interactive group unit is preferably 5 to 95 mol % and more preferably 10 to 95 mol % with respect to the total repeating units in the polymer, from the viewpoint of adsorptivity to a plating catalyst or a precursor thereof.

<<Suitable Aspect 2 of Polymer>>

The second preferred aspect of the polymer may be, for example, a copolymer containing repeating units represented by Formula (A), Formula (B), and Formula (C).

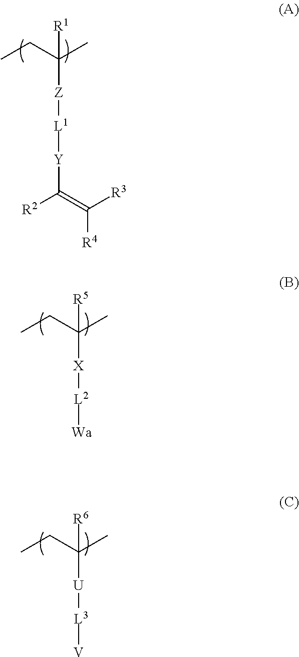

The repeating unit represented by Formula (A) is the same as the repeating unit represented by Formula (a), and the same also applies to the description of each group.

R⁵, X, and L² in the repeating unit represented by Formula (B) is the same as R⁵, X and L² in the repeating unit represented by Formula (b), and the same also applies to the description of each group.

Wa in Formula (B) represents a group capable of interacting with a plating catalyst or a precursor thereof, excluding a hydrophilic group or a precursor group thereof represented by V to be described hereinafter. Among them, preferred is a cyano group or an ether group.

In Formula (C), R⁶'s each independently represent a hydrogen atom or a substituted or unsubstituted alkyl group.

In Formula (C), U represents a single bond or a substituted or unsubstituted divalent organic group. The definition of the divalent organic group is the same as that of the above-mentioned divalent organic group represented by X, Y, and Z. U is preferably a single bond, an ester group (—COO—), an amide group (—CONH—), an ether group (—O—), or a substituted or unsubstituted divalent aromatic hydrocarbon group, from the viewpoint of easy polymer synthesis and superior adhesiveness of a metal layer.

In Formula (C), L³ represents a single bond or a substituted or unsubstituted divalent organic group. The definition of the divalent organic group is the same as that of the above-mentioned divalent organic group represented by L¹ and L². L³ is preferably a single bond, or a divalent aliphatic hydrocarbon group, a divalent aromatic hydrocarbon group, or a group formed by combining these groups, from the viewpoint of easy polymer synthesis and superior adhesiveness of a metal layer.

In Formula (C), V represents a hydrophilic group or a precursor group thereof. The hydrophilic group is not particularly limited as long as it is a group exhibiting hydrophilicity, and examples thereof include a hydroxyl group and a carboxylic acid group. The precursor group of the hydrophilic group refers to a group capable of generating a hydrophilic group by a predetermined treatment (for example, treatment with an acid or alkali), and examples thereof include a carboxyl group protected with a 2-tetrahydropyranyl (THP) group.

The hydrophilic group is preferably an ionic polar group from the viewpoint of interaction with a plating catalyst or a precursor thereof. Specific examples of the ionic polar group include a carboxylic acid group, a sulfonate group, a phosphate group, and a boronate group. Among them, preferred is a carboxylic acid group from the viewpoint of moderate acidity (not degrading other functional groups).

The preferred content of each unit in the second preferred aspect of the polymer is as follows.

The content of the repeating unit represented by Formula (A) is preferably 5 to 50 mol % and more preferably 5 to 30 mol % with respect to the total repeating units in the polymer, from the viewpoint of reactivity (curability and polymerizability) and inhibition of gelation during synthesis.

The content of the repeating unit represented by Formula (B) is preferably 5 to 75 mol % and more preferably 10 to 70 mol % with respect to the total repeating units in the polymer, from the viewpoint of adsorptivity to a plating catalyst or a precursor thereof.

The content of the repeating unit represented by Formula (C) is preferably 10 to 70 mol %, more preferably 20 to 60 mol %, and still more preferably 30 to 50 mol % with respect to the total repeating units in the polymer, from the viewpoint of developability with an aqueous solution and humidity-resistant adhesiveness.

Specific examples of the above-mentioned polymer include polymers described in paragraphs [0106] to [0112] of JP2009-007540A, polymers described in paragraphs [0065] to [0070] of JP2006-135271A, and polymers described in paragraphs [0030] to [0108] of US2010-080964A.

These polymers can be produced by known methods (for example, methods in the literature listed above).

<<Suitable Aspect of Monomer>>

In the case where the compound is a so-called monomer, a compound represented by Formula (X) can be mentioned as one suitable aspect.

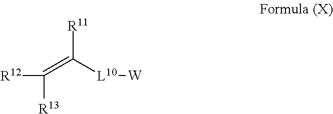

In Formula (X), R¹¹ to R¹³ each independently represent a hydrogen atom or a substituted or unsubstituted alkyl group. Examples of the unsubstituted alkyl group include a methyl group, an ethyl group, a propyl group, and a butyl group. Examples of the substituted alkyl group include a methyl group, an ethyl group, a propyl group, and a butyl group each of which is substituted with a methoxy group, a chlorine atom, a bromine atom, a fluorine atom, or the like. R¹¹ is preferably a hydrogen atom or a methyl group. R¹² is preferably a hydrogen atom. R¹³ is preferably a hydrogen atom.

L¹⁰ represents a single bond or a divalent organic group. Examples of the divalent organic group include a substituted or unsubstituted aliphatic hydrocarbon group (preferably having 1 to 8 carbon atoms), a substituted or unsubstituted aromatic hydrocarbon group (preferably having 6 to 12 carbon atoms), —O—, —S—, —SO₂—, —N(R)— (R: alkyl group), —CO—, —NH—, —COO—, —CONH—, or a group formed by combining these groups (for example, an alkyleneoxy group, an alkyleneoxycarbonyl group, or an alkylenecarbonyloxy group).

The substituted or unsubstituted aliphatic hydrocarbon group is preferably a methylene group, an ethylene group, a propylene group or a butylene group, or such a group substituted with a methoxy group, a chlorine atom, a bromine atom, a fluorine atom, or the like.

The substituted or unsubstituted aromatic hydrocarbon group is preferably an unsubstituted phenylene group, or a phenylene group substituted with a methoxy group, a chlorine atom, a bromine atom, a fluorine atom, or the like.

In Formula (X), one suitable aspect of L¹⁰ may be, for example, a —NH-aliphatic hydrocarbon group- or a —CO-aliphatic hydrocarbon group-.

W has the same definition as W in Formula (b) and represents an interactive group. The definition of the interactive group is as described above.

In Formula (X), a suitable aspect of W may be, for example, an ionic polar group and is more preferably a carboxylic acid group.

In the case where the above-mentioned compound is a so-called monomer, a compound represented by Formula (1) may be mentioned as one suitable aspect.

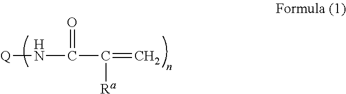

In Formula (1), Q represents an n-valent linking group, and R represents a hydrogen atom or a methyl group. n represents an integer of 2 or more.

R^{a} represents a hydrogen atom or a methyl group, preferably a hydrogen atom.

From the viewpoint of further improving the adhesiveness between the substrate and the metal layer, the valence n of Q is 2 or more, preferably 2 or more and 6 or less, more preferably 2 or more and 5 or less, and still more preferably 2 or more and 4 or less.

Examples of the n-valent linking group represented by Q include a group represented by the Formula (1A), a group represented by the formula (1B),

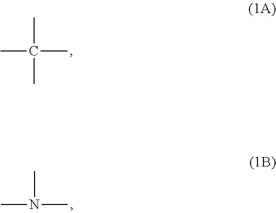

—NH—, —NR (where R represents an alkyl group)-, —O—, —S—, a carbonyl group, an alkylene group, an alkenylene group, an alkynylene group, a cycloalkylene group, an aromatic group, a heterocyclic group, or a group obtained by combining two or more of these groups.

With respect to the compound represented by Formula (X), reference can be appropriately made to the description of paragraphs [0019] to [0034] of JP2013-43946A and paragraphs [0070] to [0080] of JP2013-43945A.

(Composition Y)

The Composition Y is a composition containing a compound having an interactive group and a compound having a polymerizable group. That is, the plated-layer precursor layer contains two compounds: a compound having an interactive group and a compound having a polymerizable group. The definition of the interactive group and the polymerizable group is as described above.

The definition of the interactive group contained in the compound having an interactive group is as described above. Such a compound may be a low molecular weight compound or a high molecular weight compound. A suitable aspect of the compound having an interactive group may be, for example, a polymer having a repeating unit represented by Formula (b) (for example, polyacrylic acid). Further, it is preferred that a polymerizable group is not contained in the compound having an interactive group.

The compound having a polymerizable group is a so-called monomer, and is preferably a polyfunctional monomer having two or more polymerizable groups from the viewpoint of superior hardness of a patterned plated layer to be formed. With regard to the polyfunctional monomer, specifically, it is preferred to use a monomer having 2 to 6 polymerizable groups. From the viewpoint of mobility of molecules during the crosslinking reaction which affects the reactivity, the molecular weight of the polyfunctional monomer to be used is preferably 150 to 1,000 and more preferably 200 to 700. Further, the space (distance) between a plurality of polymerizable groups is preferably 1 to 15 atoms and more preferably 6 to 10 atoms. Specific examples of the polyfunctional monomer include the compound represented by Formula (1).

The compound having a polymerizable group may contain an interactive group.

The mass ratio of the compound having an interactive group: the compound having a polymerizable group (mass of the compound having an interactive group/mass of the compound having a polymerizable group) is not particularly limited, but it is preferably 0.1 to 10 and more preferably 0.5 to 5 in terms of balance of strength and plating suitability of a patterned plated layer to be formed.

The content of Compound X (or Composition Y) in the plated-layer precursor layer is not particularly limited, but it is preferably 50% by mass or more and more preferably 80% by mass or more with respect to the total mass of the plated-layer precursor layer. The upper limit is not particularly limited, but it is preferably 99.5% by mass or less.

The plated-layer precursor layer may contain components other than the above-mentioned polymerization initiator, Compound X, and Composition Y.

For example, the plated-layer precursor layer may contain a monomer (excluding the compound represented by Formula (1)). The inclusion of a monomer can result in appropriate control of a crosslinking density or the like in the patterned plated layer.

The monomer to be used is not particularly limited. For example, there are a compound having an ethylenically unsaturated bond as a compound having addition polymerizability, and a compound having an epoxy group as a compound having a ring-opening polymerizability. Among them, from the viewpoint of improving a crosslinking density in the patterned plated layer, it is preferred to use a polyfunctional monomer. The polyfunctional monomer refers to a monomer having two or more polymerizable groups. Specifically, it is preferred to use a monomer having 2 to 6 polymerizable groups.

If necessary, other additives (for example, a sensitizer, a curing agent, a polymerization inhibitor, an antioxidant, an antistatic agent, a filler, particles, a flame retardant, a surfactant, a lubricant, and a plasticizer) may be added to the plated-layer precursor layer.

<Method of Forming Plated-Layer Precursor Layer>

The method of forming the plated-layer precursor layer on the surface of the undercoat on the substrate is not particularly limited and examples thereof include a method in which a composition containing the above-mentioned various components is applied to the surface of the undercoat on the substrate to form a plated-layer precursor layer (coating method), and a method in which a plated-layer precursor layer is formed on a temporary substrate and is then transferred to the surface of the undercoat on the substrate (transfer method). Among them, a coating method is preferable from the viewpoint of easily controlling the thickness.

Hereinafter, aspects of the coating method will be described in detail.

The composition used in the coating method preferably contains at least the above-mentioned polymerization initiator and Compound X or Composition Y. The composition may contain the above-mentioned other components, if necessary.

Further, the composition preferably contains a solvent, from the viewpoint of handleability. The solvent that can be used is not particularly limited. For example, a solvent used for forming the above-mentioned undercoat can be used. The content of the solvent in the composition is not particularly limited, but it is preferably 50% to 98% by mass and more preferably 70% to 95% by mass with respect to the total amount of the composition.

In the case where the content of the solvent is within the above-specified range, handleability of the composition is excellent and control of the layer thickness is easy.

In the case of the coating method, the method of applying the composition onto the substrate is not particularly limited, and a known method (for example, a spin coating method, a die coating method, or a dip coating method) can be used.

In the case where the plated-layer precursor layer is disposed on both surfaces of the substrate, the composition may be applied to each surface of the substrate one by one, or the substrate may be immersed in the composition so that the composition is applied to both surfaces of the substrate at once.

From the viewpoint of handleability and production efficiency, an aspect of forming a plated-layer precursor layer by applying the composition onto a substrate, and performing a drying treatment as necessary to remove the remaining solvent is preferable.

The conditions of the drying treatment are not particularly limited, but from the viewpoint of superior productivity, it is preferable to carry out the drying treatment at room temperature to 220° C. (preferably 50° C. to 120° C.) for 1 to 30 minutes (preferably 1 to 10 minutes).

The thickness of the plated-layer precursor layer is not particularly limited, but it is preferably 0.01 to 20 μm, more preferably 0.1 to 10 μm, and still more preferably 0.1 to 5 μm.

[Electroconductive Film]

Next, the configuration of the electroconductive film of the present invention will be described in detail, and the method for producing the electroconductive film of the present invention and the film having a patterned plated layer of the present invention and the method for producing the same will also be described in detail.

The electroconductive film of the present invention includes a substrate, an undercoat disposed on the substrate, a patterned plated layer disposed on the undercoat, and a metal layer laminated on the surface of the patterned plated layer by a plating treatment.

FIG. 2 is a schematic cross-sectional view showing an example of an embodiment of the electroconductive film of the present invention. The electroconductive film 100 of FIG. 2 includes a substrate 12, an undercoat 15 disposed on the substrate 12, a patterned plated layer 20 disposed on the undercoat 15, and a metal layer 22 disposed on the surface of the patterned plated layer 20 by a plating treatment.

Hereinafter, the electroconductive film of the present invention will be described with reference to the drawings by way of an example of a method for producing the electroconductive film 100. In addition, a method for producing the film having a plated-layer precursor layer of the present invention and a method for producing the film having a patterned plated layer of the present invention will also be described. The embodiments of the present invention are not limited to the aspects described below.

The electroconductive film of the present invention can be produced by a production method having Step 1, Step 2, and Step 3 given below.

Step 1: a step of forming a film having a plated-layer precursor layer in which an undercoat is formed on the substrate from the substrate side and a plated-layer precursor layer is formed on the undercoat,

Step 2: a step of forming a film having a patterned plated layer in which a patterned plated layer is formed by subjecting a plated-layer precursor layer to patternwise exposure to cure the film into a pattern, and

Step 3: a step of forming a metal layer in which a metal layer is formed on the patterned plated layer by a plating treatment (electroconductive film forming step).

[Step 1: Step of Forming Film Having Plated-Layer Precursor Layer]

Step 1 is a step of laminating and forming an undercoat and a plated-layer precursor layer on a substrate in this order from the substrate side to form a film having a plated-layer precursor layer. That is, Step 1 is a step of forming the film having a plated-layer precursor layer 10 as shown in FIG. 1.

In Step 1, an undercoat 15 is first formed on a substrate 12, and a plated-layer precursor layer (unexposed coating film) 30 is disposed on the undercoat 15. The undercoat 15 is formed, for example, by forming a coating film on the substrate 12 by the above-mentioned coating method or the like, and then curing the coating film by exposure or the like as necessary.

[Step 2: Step of Forming Film Having Patterned Plated Layer]

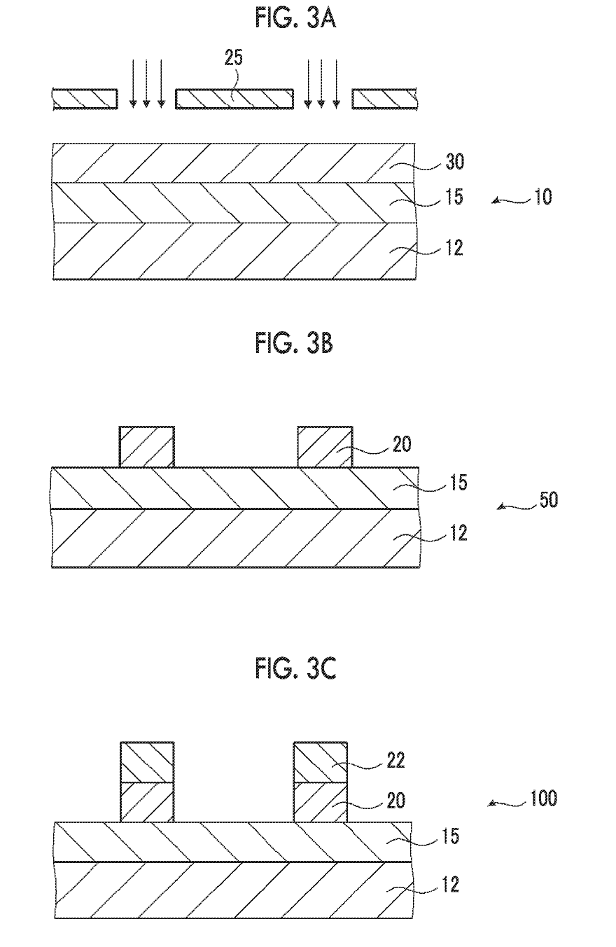

Step 2 is a step of subjecting the coating film of the plated-layer precursor layer to patternwise exposure to form a patterned plated layer on the substrate. More specifically, as shown in FIG. 3A, Step 2 is a step in which the plated-layer precursor layer 30 constituting the film having a plated-layer precursor layer 10 is subjected to patternwise exposure as indicated by black arrows through a photo mask 25 to accelerate the reaction of the polymerizable group to cure the film and then the unexposed region is removed to obtain a patterned plated layer 20 (FIG. 3B).

According to the function of the interactive group, the patterned plated layer 20 of the film 50 having a patterned plated layer formed by the above step adsorbs (adheres to) a plating catalyst or a precursor thereof in Step 3 to be described later. That is, the patterned plated layer 20 functions as a good layer of receiving the plating catalyst or the precursor thereof. In addition, the polymerizable group is utilized for bonding of compounds through a curing treatment by exposure, and therefore a patterned plated layer having excellent hardness can be obtained.

The method of exposing the plated-layer precursor layer 30 on the substrate in a patternwise manner is not particularly limited, and examples thereof include a method of irradiating actinic rays or radiation. As irradiation with actinic rays, a UV (ultraviolet) lamp or light irradiation by visible light or the like is used. Examples of the light source include a mercury lamp, a metal halide lamp, a xenon lamp, a chemical lamp, and a carbon arc lamp. Examples of the radiation include electron beams, X-rays, ion beams, and far infrared rays.

Specific aspects of exposing the coating film on the substrate in a patternwise manner suitably include scanning exposure by an infrared laser, high-illumination flash exposure such as a xenon discharge lamp exposure using a mask, and infrared lamp exposure using a mask. By exposing the coating film, the polymerizable group contained in the compound in the coating film is activated to result in crosslinking between the compounds, and the curing of the layer progresses. The exposure energy may be about 10 to 8,000 mJ/cm² and is preferably in the range of 50 to 3,000 mJ/cm².

Next, the unexposed region in the plated-layer precursor layer 30 is removed to form the patterned plated layer 20.

The removal method is not particularly limited, and an optimum method is appropriately selected according to the compound to be used. For example, a method in which an alkaline solution (preferably pH: 13.0 to 13.8) is used as a developer can be mentioned. In the case where an alkaline solution is used to remove an unexposed region, there are a method of immersing a substrate having an exposed coating film in a solution (immersion method), a method of applying a developer onto a substrate having an exposed coating film (coating method), and the like, among which the immersion method is preferable. In the case of the immersion method, the immersion time is preferably about 1 to 30 minutes from the viewpoints of productivity and workability.

Another method may be, for example, a method in which a solvent in which a compound to be used is dissolved is used as a developer and the substrate is immersed in the solvent.

<Patterned Plated Layer>

The patterned plated layer is a layer containing the above-mentioned interactive group. As will be described later, the patterned plated layer is subjected to a plating treatment.

The thickness of the patterned plated layer formed by the above treatment is not particularly limited, but from the viewpoint of productivity, it is preferably 0.01 to 10 μm, more preferably 0.2 to 5 μm, and still more preferably 0.3 to 1.0 μm.

The pattern shape of the patterned plated layer is not particularly limited, and it is adjusted according to a place where a metal layer described later is desired to be formed.

The pattern shape may be, for example, a mesh pattern. In the case of a mesh pattern, a length W of one side of a lattice (opening portion) in the mesh pattern is preferably 800 μm or less and more preferably 600 μm or less and is preferably 50 μm or more and more preferably 400 μm or more. The shape of the lattice is not particularly limited, and it may substantially be a diamond shape or a polygonal shape (for example, a triangular shape, a square shape, or a hexagonal shape). Further, the shape of one side may be a curved shape or an arc shape in addition to a linear shape.

The line width of the patterned plated layer is not particularly limited, but it is preferably 30 μm or less, more preferably 15 μm or less, still more preferably 10 μm or less, particularly preferably 9 μm or less, and most preferably 7 μm or less, from the viewpoint of low resistance of the metal layer disposed on the patterned plated layer. On the other hand, the lower limit thereof is preferably 0.5 μm or more and more preferably 1.0 μm or more.

[Step 3: Step of Forming Metal Layer]

Step 3 is a step in which a plating catalyst or a precursor thereof is applied to the patterned plated layer formed in Step 2, and a plating treatment is carried out on the patterned plated layer to which a plating catalyst or a precursor thereof has been applied, so that a metal layer is formed on the patterned plated layer. As shown in FIG. 3C, by carrying out the present step, a metal layer 22 is disposed on a patterned plated layer 20, so an electroconductive film 100 is obtained.

Hereinafter, the step of applying a plating catalyst or a precursor thereof to the patterned plated layer (Step 3-1) and the step of carrying out a plating treatment on the patterned plated layer to which a plating catalyst or a precursor thereof has been applied (Step 3-2) will be described separately.

(Step 3-1: Catalyst Applying Step)

In the present step, first, a plating catalyst or a precursor thereof is applied to a patterned plated layer. The above-mentioned interactive group contained in the patterned plated layer adheres to (adsorbs) the applied plating catalyst or precursor thereof, according to the function thereof. More specifically, the plating catalyst or the precursor thereof is applied in the patterned plated layer and on the surface of the patterned plated layer.

The plating catalyst or the precursor thereof functions as a catalyst or electrode of a plating treatment. Therefore, the type of the plating catalyst or the precursor thereof to be used is appropriately determined in accordance with the type of the plating treatment.

Further, the plating catalyst or the precursor thereof to be used is preferably an electroless plating catalyst or a precursor thereof.

Any plating catalyst may be used as the plating catalyst used in the present step as long as it serves as an active nucleus during plating. Specifically, a metal having a catalytic capacity of the autocatalytic reduction reaction (which is known as a metal capable of electroless plating with lower ionization tendency than Ni) may be used. Specific examples thereof include Pd, Ag, Cu, Ni, Pt, Au, and Co. Among them, particularly preferred is Ag, Pd, Pt, or Cu from the viewpoint of high catalytic capacity.

A metallic colloid may be used as the plating catalyst.

The plating catalyst precursor in the present step can be used without any particular limitation as long as it may be converted into the plating catalyst by a chemical reaction. Metal ions of the metals illustrated above for the plating catalyst are mainly used. The metal ions which are the plating catalyst precursors are converted by the reduction reaction into zero-valent metals which are the plating catalysts. After the metal ion as the plating catalyst precursor is applied to the patterned plated layer, the electroless plating catalyst precursor may be separately converted into a zero-valent metal as the plating catalyst by the reduction reaction before being immersed in a plating bath. Alternatively, the plating catalyst precursor may be immersed into the plating bath without any treatment to be converted into a metal (plating catalyst) by the action of a reducing agent in the plating bath.

The metal ion is preferably applied to the patterned plated layer using a metal salt. The metal salt to be used is not particularly limited as long as it is dissolved in an appropriate solvent and dissociated into a metal ion and a base (anion), and example thereof include M(NO₃)ₙ, MClₙ, M_{2/n}(SO₄), and M_{3/n}(PO₄) (M represents an n-valent metal atom). As metal ions, those metal ions dissociated from the foregoing metal salts can be suitably used. Specific examples thereof include Ag ions, Cu ions, Al ions, Ni ions, Co ions, Fe ions, and Pd ions, among which those capable of being coordinated at multiple sites are preferable, and Ag ions or Pd ions are more preferable from the viewpoints of the number of types of functional groups capable of being coordinated and the catalytic capacity.

As a method for applying a metal ion to the patterned plated layer, for example, a solution containing a dissociated metal ion may be prepared by dissolving a metal salt in an appropriate solvent, and then the solution may be applied onto the patterned plated layer, or alternatively, a substrate on which the patterned plated layer is formed may be immersed in the solution.

Water or an organic solvent is appropriately used as the solvent. The organic solvent is preferably a solvent capable of permeating the patterned plated layer. For example, acetone, methyl acetoacetate, ethyl acetoacetate, ethylene glycol diacetate, cyclohexanone, acetylacetone, acetophenone, 2-(1-cyclohexenyl)cyclohexanone, propylene glycol diacetate, triacetin, diethylene glycol diacetate, dioxane, N-methylpyrrolidone, dimethyl carbonate, or dimethyl cellosolve may be used.

The concentration of the plating catalyst or the precursor thereof in the solution is not particularly limited, but it is preferably 0.001% to 50% by mass and more preferably 0.005% to 30% by mass.

The contact time is preferably about 30 seconds to 24 hours and more preferably about 1 minute to 1 hour.

The adsorbed amount of the plating catalyst or the precursor thereof of the patterned plated layer varies depending on a plating bath species to be used, a catalyst metal species, an interactive group species of a patterned plated layer, usage and the like, but it is preferably 5 to 1,000 mg/m², more preferably 10 to 800 mg/m², and still more preferably 20 to 600 mg/m² from the viewpoint of a deposition property of plating.

(Step 3-2: Plating Treatment Step)

Next, a plating treatment is carried out on the patterned plated layer to which a plating catalyst or a precursor thereof has been applied.

The method of a plating treatment is not particularly limited, and examples thereof include an electroless plating treatment and an electrolytic plating treatment (electroplating treatment). In the present step, an electroless plating treatment may be carried out alone, or an electrolytic plating treatment may be further carried out following an electroless plating treatment.

In the present specification, a so-called silver mirror reaction is included as one type of the above-mentioned electroless plating treatment. Thus, a desired patterned metal layer may be formed by reducing the adhered metal ions, for example, by a silver mirror reaction or the like, and thereafter an electrolytic plating treatment may be further carried out.

Hereinafter, the procedure of the electroless plating treatment and electrolytic plating treatment will be described in detail.

The electroless plating treatment refers to an operation of allowing metals to be deposited through a chemical reaction using a solution in which metal ions expected to be deposited as plating are dissolved.

The electroless plating treatment in the present step is carried out by washing the substrate including the patterned plated layer to which metal ions have been applied with water to remove extra metal ions, and then immersing the substrate in an electroless plating bath. A known electroless plating bath can be used as the electroless plating bath to be used. In addition, metal ions are reduced and then electroless plating is carried out in the electroless plating bath.

Separately from the aspect of using the above-mentioned electroless plating liquid, the reduction of metal ions in the patterned plated layer can be performed by preparing a catalyst activating liquid (reducing liquid) as a separate step before the electroless plating treatment. The catalyst activating liquid is a liquid in which a reducing agent capable of reducing a metal ion into a zero-valent metal is dissolved, and the concentration of the reducing agent with respect to the entire liquid is preferably 0.1% to 50% by mass and more preferably 1% to 30% by mass. As the reducing agent, a boron-based reducing agent such as sodium borohydride or dimethylamine borane, formaldehyde, or hypophosphorous acid can be used.

During the immersion, it is preferred that the substrate is immersed while stirring or shaking.

Typically, the composition of the electroless plating bath mainly includes 1. metal ions for plating, 2. reducing agent, and 3. additive (stabilizer) that improves the stability of metal ions in addition to a solvent (for example, water). In addition to these, the plating bath may include a known additive such as a stabilizer for a plating bath.

The organic solvent used for the electroless plating bath is required to be a solvent which is soluble in water. From this viewpoint, ketones such as acetone; and alcohols such as methanol, ethanol, and isopropanol are preferable. As the type of metal used for the electroless plating bath, copper, tin, lead, nickel, gold, silver, palladium, or rhodium is known. Among them, from the viewpoint of conductivity, copper, silver, or gold is preferable and copper is more preferable. Further, an optimal reducing agent and an optimal additive are selected according to the metal.

The immersion time in the electroless plating bath is preferably 1 minute to 6 hours and more preferably 1 minute to 3 hours.

The electrolytic plating treatment refers to an operation of allowing metals to be deposited by an electric current using a solution in which metal ions expected to be deposited as plating are dissolved.

Further, in the present step as described above, the electrolytic plating treatment may be carried out as necessary, after the electroless plating treatment. According to such an aspect, the thickness of the patterned metal layer to be formed can be suitably adjusted.

As the method of electrolytic plating, a conventional known method can be used. Further, examples of metals used for electrolytic plating include copper, chromium, lead, nickel, gold, silver, tin, and zinc. Among them, from the viewpoint of conductivity, copper, gold, or silver is preferable and copper is more preferable.

In addition, the film thickness of the metal layer obtained by the electrolytic plating can be controlled by adjusting the concentration of a metal contained in the plating bath or the current density.

The thickness of the metal layer to be formed by the above-mentioned procedures is not particularly limited and the optimal thickness can be suitably selected according to the intended use, but it is preferably 0.1 μm or greater, more preferably 0.5 μm or greater, and still more preferably 1 to 30 μm, from the viewpoint of conductive properties.

Moreover, the type of metal constituting the metal layer is not particularly limited and examples thereof include copper, chromium, lead, nickel, gold, silver, tin, and zinc. Among them, from the viewpoint of conductivity, copper, gold, or silver is preferable and copper or silver is more preferable.

The pattern shape of the metal layer is not particularly limited, but the metal layer may have, for example, a mesh pattern because the metal layer is disposed on the patterned plated layer, so that the shape thereof is adjusted by the pattern shape of the patterned plated layer. The metal layer having a mesh pattern can be suitably applied as a sensor electrode in a touch panel. In the case where the pattern shape of the metal layer is a mesh pattern, the range of the length W of one side of the lattice (opening portion) in the mesh pattern, the suitable aspect of the lattice shape, and the line width of the metal layer are the same as in the above-mentioned aspect of a patterned plated layer.

[Applications]

The electroconductive film having a metal layer obtained by the foregoing treatment can be applied to various uses and can be applied to various applications such as a touch panel (or a touch panel sensor), a semiconductor chip, various electric wiring boards, a flexible printed circuit (FPC), a chip on film (COF), a tape automated bonding (TAB), an antenna, a multilayer wiring board, and a mother board. Among them, it is preferable to use such an electroconductive film for a touch panel sensor (electrostatic capacitance touch panel sensor). In the case where the electroconductive laminate is applied to a touch panel sensor, the metal layer in the electroconductive film functions as a detection electrode or a lead-out wiring in the touch panel sensor.

In the present specification, a combination of a touch panel sensor and various display devices (for example, a liquid crystal display device and an organic electroluminescence (EL) display device) is called a touch panel. The touch panel is preferably, for example, a so-called electrostatic capacitance touch panel.

### EXAMPLES

Hereinafter, the present invention will be described in more detail with reference to Examples. The materials, the use amounts, the ratios, the treatment contents, the treatment procedures, and the like shown in the following Examples can be appropriately changed without departing from the gist of the present invention. Therefore, the scope of the present invention should not be limitatively interpreted by the following Examples.

### Comparative Example 1

(Preparation of Plated Layer Forming Composition)

The following components were mixed to obtain a plated layer forming composition.

| | | |
|---|---|---|
| Isopropanol | 94.9 | parts by mass |
| Polyacrylic acid | 3 | parts by mass |
| (manufactured by Wako Pure | | |
| Chemical Industries, Ltd.) | | |
| Methylenebisacrylamide | 2 | parts by mass |
| (manufactured by Wako Pure | | |
| Chemical Industries, Ltd.) | | |
| IRGACURE127 | 0.1 | parts by mass |
| (manufactured by BASF Corporation) | | |

(Production of Film Having Plated-Layer Precursor Layer)

First, MT1007 (manufactured by NIPPONPAINT Co., Ltd.) was applied to one surface of a roll-like polyethylene terephthalate (PET) film with a thickness of 50 m (trade name “A4300”, manufactured by Toyobo Co., Ltd.) so as to have a film thickness of 2 μm after drying, followed by further drying at 80° C. for 1 minute to form a coating film. Subsequently, using a metal halide ultraviolet (UV) lamp, the coating film was cured by irradiation of light at an exposure amount of 0.5 J/cm² to form an undercoat 1. The hardness evaluation and the friction coefficient evaluation described below were carried out on a film having the undercoat 1 on the substrate. Then, a laminate film (trade name “PAC2-50-THK”, manufactured by Sun A. Kaken Co., Ltd.) was laminated to the undercoat 1 and then wound into a roll.

A film having the undercoat 1 and the laminate film on one surface of the PET film produced as above was unwound from the roll and MT1007 (manufactured by NIPPONPAINT Co., Ltd.) was also applied to the opposite surface of the PET film (that is, the surface on which the undercoat 1 and the laminate film were not disposed) so as to have a film thickness of 2 μm after drying, followed by further drying at 80° C. for 1 minute to form a coating film. Subsequently, using a metal halide UV lamp, the coating film was cured by irradiation of light at an exposure amount of 0.5 J/cm² to form an undercoat 2. A film laminated with the undercoat 1, the undercoat 2, and the laminate film, which was produced through the above steps, was wound on a roll.

Next, a plated layer forming composition was applied to the surface not laminated with the laminate film (that is, the surface of the undercoat 2) so as to have a film thickness of 0.6 μm after drying, followed by further drying at 80° C. for 1 minute to form a coating film of the plated-layer precursor layer 2. Subsequently, the film having the plated-layer precursor layer 2 formed thereon was wound on a roll.

Finally, the film having the plated-layer precursor layer 2 formed thereon was delivered from the roll while peeling off the laminate film, and the plated layer forming composition was applied onto the surface from which the laminate film was peeled off (that is, the surface of the undercoat 1) so as to have a film thickness of 0.6 μm after drying, followed by further drying at 80° C. for 1 minute to form a coating film of the plated-layer precursor layer 1. Subsequently, while laminating a laminate film to the coating film of the plated-layer precursor layer 1, it was wound around a roll to obtain a film R-1 having a plated-layer precursor layer.

In the case where the film R-1 having a plated-layer precursor layer is produced by the roll-to-roll process, there is also a roller in contact with the undercoats 1 and 2 on the PET film during the conveyance of the PET film.

(Production of Electroconductive Film)

The produced film R-1 having a plated-layer precursor layer was cut into 150 mm square. Subsequently, the plated-layer precursor layer 2 of the cut film R-1 having a plated-layer precursor layer was irradiated with 1 J/cm² using a high pressure mercury lamp through a 150 mm square mask provided with a conductive pattern. Thereafter, water at 40° C. was sprayed for 2 minutes in a shower form to carry out patternwise development to obtain a film R2-1 having a patterned plated layer.

Next, the obtained film R2-1 having a patterned plated layer was immersed for 5 minutes in a Pd ion-providing liquid obtained by 4-fold dilution of only the “MAT-A liquid” of a Pd catalyst-providing liquid “MAT” manufactured by Uemura Kogyo Co., Ltd. After immersion, the film R2-1 having a patterned plated layer was washed. Thereafter, the obtained film R2-1 having a patterned plated layer was immersed for 5 minutes in a Pd reducing agent “MAB” manufactured by Uemura Kogyo Co., Ltd. Subsequently, the immersed film R2-1 having a patterned plated layer was immersed in a plating liquid “PEA” manufactured by Uemura Kogyo Co., Ltd. for 5 minutes to deposit copper in a patternwise manner on the plated layer to obtain an electroconductive film R3-1.

### Comparative Example 2

First, a composition containing 10% by mass of HNBR (hydrogenated nitrile rubber, Zetpol 0020, manufactured by Zeon Corporation) dissolved in cyclohexanone was applied to one surface of a roll-like polyethylene terephthalate (PET) film with a thickness of 50 μm (trade name “A4300”, manufactured by Toyobo Co., Ltd.) so as to have a film thickness of 2 μm after drying, followed by further drying at 80° C. for 1 minute to form a coating film. Subsequently, using a metal halide ultraviolet (UV) lamp, the coating film was cured by irradiation of light at an exposure amount of 0.5 J/cm² to form an undercoat 1.

In the case where the obtained film having the undercoat 1 formed on the substrate was roll-conveyed so that the undercoat 1 was on the side of the roller surface, the film got stuck and did not slide in the case of being contacted with the roller, and therefore the roll did not rotate. That is, roll handling could not be done.

### Examples 1 to 7 and Comparative Examples 3 to 6

### Example 1

Based on the compositional ratios shown in Table 1, polyethylene glycol (PEG Mw (weight-average molecular weight): 400, manufactured by Tokyo Chemical Industry Co., Ltd.) and ethoxylated isopropylidenediphenol (bisphenol A-EO added, manufactured by Aldrich Chemical Co., Inc.) as diol compound s (“Diol components” in the table), and isophorone diisocyanate (IPDI, manufactured by Wako Pure Chemical Industries, Ltd.) as a diisocyanate compound (“Diisocyanate components” in the table) were dissolved in methyl ethyl ketone and stirred at 60° C. for 5 hours.

Subsequently, based on the compositional ratio shown in Table 1, hydroxybutyl acrylate (HBA, manufactured by Tokyo Chemical Industry Co., Ltd.) as a crosslinking component and dibutyltin dilaurate (0.1% in terms of mass ratio with respect to the solid component, manufactured by Wako Pure Chemical Industries, Ltd.) as a catalyst were further added to the obtained composition, and the mixture was further stirred for 5 hours.

Irgacure 2959 (1% in terms of mass ratio with respect to the solid component, manufactured by BASF Corporation) as an initiator was added to the obtained polymer, and polydimethylsiloxane (weight-average molecular weight of 770, 0.1% in terms of mass ratio with respect to the solid component, manufactured by Alfa Aesar Co., Ltd.) as an additive was added thereto to prepare undercoat material 1.

Table 1 summarizes the composition of the undercoat material 1. The solvent was added such that the total mass of the composition of the undercoat material 1 was 100 parts by mass and further the solvent was prepared such that the blending ratio (mass ratio) of methyl ethyl ketone and propylene glycol monomethyl ether acetate (PGMEA) was 7:3.

A film T-1 having a plated-layer precursor layer was produced in the same manner as in Comparative Example 1, except that, in the production of the film R-1 having a plated-layer precursor layer of Comparative Example 1, an undercoat 1 and an undercoat 2 (each having a film thickness after drying of 2 μm) were produced using the undercoat material 1 in place of MT 1007 (manufactured by NIPPONPAINT Co., Ltd.). Further, a film T2-1 having a patterned plated layer and an electroconductive film T3-1 were obtained in the same manner as in Comparative Example 1.

### Example 2

An undercoat material 2 was prepared in the same manner as in the undercoat material 1, except that the components shown in Table 1 were used. Also, a film T-2 having a plated-layer precursor layer was produced in the same manner as in Comparative Example 1, except that an undercoat 1 and an undercoat 2 (each having a film thickness after drying of 2 μm) were produced using the undercoat material 2. Further, a film T2-2 having a patterned plated layer and an electroconductive film T3-2 were obtained in the same manner as in Comparative Example 1.

### Example 3

An undercoat material 3 was prepared in the same manner as in the undercoat material 1, except that the components shown in Table 1 were used. Also, a film T-3 having a plated-layer precursor layer was produced in the same manner as in Comparative Example 1, except that an undercoat 1 and an undercoat 2 (each having a film thickness after drying of 2 μm) were produced using the undercoat material 3. Further, a film T2-3 having a patterned plated layer and an electroconductive film T3-3 were obtained in the same manner as in Comparative Example 1.

### Example 4

An undercoat material 4 was prepared in the same manner as in the undercoat material 1, except that the components shown in Table 1 were used. Also, a film T-4 having a plated-layer precursor layer was produced in the same manner as in Comparative Example 1, except that an undercoat 1 and an undercoat 2 (each having a film thickness after drying of 2 μm) were produced using the undercoat material 4. Further, a film T2-4 having a patterned plated layer and an electroconductive film T3-4 were obtained in the same manner as in Comparative Example 1.

### Example 5

An undercoat material 5 was prepared in the same manner as in the undercoat material 1, except that the components shown in Table 1 were used. Also, a film T-5 having a plated-layer precursor layer was produced in the same manner as in Comparative Example 1, except that an undercoat 1 and an undercoat 2 (each having a film thickness after drying of 2 μm) were produced using the undercoat material 5. Further, a film T2-5 having a patterned plated layer and an electroconductive film T3-5 were obtained in the same manner as in Comparative Example 1.

### Example 6

An undercoat material 6 was prepared in the same manner as in the undercoat material 1, except that the components shown in Table 1 were used. Also, a film T-6 having a plated-layer precursor layer was produced in the same manner as in Comparative Example 1, except that an undercoat 1 and an undercoat 2 (each having a film thickness after drying of 2 μm) were produced using the undercoat material 6. Further, a film T2-6 having a patterned plated layer and an electroconductive film T3-6 were obtained in the same manner as in Comparative Example 1.

### Example 7

An undercoat material 7 was prepared in the same manner as in the undercoat material 1, except that the components shown in Table 1 were used. Also, a film T-7 having a plated-layer precursor layer was produced in the same manner as in Comparative Example 1, except that an undercoat 1 and an undercoat 2 (each having a film thickness after drying of 2 μm) were produced using the undercoat material 7. Further, a film T2-7 having a patterned plated layer and an electroconductive film T3-7 were obtained in the same manner as in Comparative Example 1.

### Comparative Example 3

An undercoat material 8 was prepared in the same manner as in the undercoat material 1, except that the components shown in Table 1 were used. Also, a film R-3 having a plated-layer precursor layer was produced in the same manner as in Comparative Example 1, except that an undercoat 1 and an undercoat 2 (each having a film thickness after drying of 2 μm) were produced using the undercoat material 8. Further, a film R2-3 having a patterned plated layer and an electroconductive film R3-3 were obtained in the same manner as in Comparative Example 1.

### Comparative Example 4

An undercoat material 9 was prepared in the same manner as in the undercoat material 1, except that the components shown in Table 1 were used. Also, a film R-4 having a plated-layer precursor layer was produced in the same manner as in Comparative Example 1, except that an undercoat 1 and an undercoat 2 (each having a film thickness after drying of 2 μm) were produced using the undercoat material 9. Further, a film R2-4 having a patterned plated layer and an electroconductive film R3-4 were obtained in the same manner as in Comparative Example 1.

### Comparative Example 5

An undercoat material 10 was prepared in the same manner as in the undercoat material 1, except that the components shown in Table 1 were used. Also, a film R-5 having a plated-layer precursor layer was produced in the same manner as in Comparative Example 1, except that an undercoat 1 and an undercoat 2 (each having a film thickness after drying of 2 μm) were produced using the undercoat material 10. Further, a film R2-5 having a patterned plated layer and an electroconductive film R3-5 were obtained in the same manner as in Comparative Example 1.

### Comparative Example 6

An undercoat material 11 was prepared in the same manner as in the undercoat material 1, except that the components shown in Table 1 were used. Also, a film R-6 having a plated-layer precursor layer was produced in the same manner as in Comparative Example 1, except that an undercoat 1 and an undercoat 2 (each having a film thickness after drying of 2 μm) were produced using the undercoat material 11. Further, a film R2-6 having a patterned plated layer and an electroconductive film R3-6 were obtained in the same manner as in Comparative Example 1.

Table 1 is shown below.

In Table 1, the blending amount of each component is based on “part by mass”. Further, the solvent was added such that the total mass of the composition of the undercoat material 1 was 100 parts by mass, and the solvent was prepared such that the blending ratio (mass ratio) of methyl ethyl ketone and PGMEA was 7:3.

In addition, each urethane (meth)acrylate of the undercoat materials 1 to 7 had a weight-average molecular weight within the range of 30,000 to 70,000.

TABLE 1

| | Composition | | | | | | | |
|---|---|---|---|---|---|---|---|---|
| | Diol components | | | Diisocyanate | | Crosslinking | | |
| | | | Bisphenol | components | | components | | |
| | PEG | PTMO | A-EO added | IPDI | HDI | HEA | HBA | DPHA |
| Undercoat | 13 | — | 3 | 17 | — | — | 0.8 | — |
| material 1 | (Mw: 400) | | | | | | | |
| Undercoat | 13 | — | 3 | — | 17 | — | 0.8 | — |
| material 2 | (Mw: 400) | | | | | | | |
| Undercoat | 13 | — | 1 | 15 | — | — | 0.4 | — |
| material 3 | (Mw: 1000) | | | | | | | |
| Undercoat | — | 13 | 3 | 17 | — | — | 0.8 | — |
| material 4 | | (Mw: 650) | | | | | | |
| Undercoat | 13 | — | 3 | 17 | — | 0.8 | — | — |
| material 5 | (Mw: 400) | | | | | | | |
| Undercoat | 14 | — | — | — | 15 | — | 0.8 | — |
| material 6 | (Mw: 400) | | | | | | | |
| Undercoat | 14 | — | — | 15 | — | — | 0.8 | — |
| material 7 | (Mw: 400) | | | | | | | |
| Undercoat | 13 | — | 3 | 17 | — | — | 0.8 | 2 |
| material 8 | (Mw: 400) | | | | | | | |
| Undercoat | 6 | — | 6 | 14 | — | — | 3 | — |
| material 9 | (Mw: 400) | | | | | | | |
| Undercoat | 6 | — | 6 | — | 14 | — | 3 | — |
| material 10 | (Mw: 400) | | | | | | | |
| Undercoat | — | 6 | 6 | — | 14 | — | 3 | — |
| material 11 | | (Mw: 650) | | | | | | |

| | Composition | | | |
|---|---|---|---|---|
| | Others | | | |
| | | Polymerization | | |
| | Dibutyltin dilaurate | initiator | Polydimethylsiloxane | Solvent |
| Undercoat | 0.1% in terms of mass | 1% in terms of mass | 0.1% in terms of mass | Balance |
| material 1 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 2 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 3 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 4 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 5 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 6 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 7 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 8 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 9 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 10 | ratio with respect to | ratio with respect to | ratio with respect to | |
| | solid component | solid component | solid component | |
| Undercoat | 0.1% in terms of mass | 1% in terms of mass | 0.1% in terms of mass | Balance |
| material 11 | ratio with respect to | ratio with respect to | ratio with respect to | |
| | solid component | solid component | solid component | |

The components in Table 1 are shown below.
Diol components

Polyethylene glycol (PEG Mw: 400, manufactured by Tokyo Chemical Industry Co., Ltd.)

Polyethylene glycol (PEG Mw: 1000, manufactured by Tokyo Chemical Industry Co., Ltd.)

Polytetramethylene oxide (PTMO Mw: 650, manufactured by Wako Pure Chemical Industries, Ltd.)

Ethoxylated isopropylidene diphenol (bisphenol A-EO added, manufactured by Aldrich Chemical Co., Inc.)
Diisocyanate components

Isophorone diisocyanate (IPDI, manufactured by Wako Pure Chemical Industries, Ltd.)

Hexamethylene diisocyanate (HDI, manufactured by Tokyo Chemical Industry Co., Ltd.)
Crosslinking components

Hydroxyethyl acrylate (HEA, manufactured by Tokyo Chemical Industry Co., Ltd.)

Hydroxybutyl acrylate (HBA, manufactured by Tokyo Chemical Industry Co., Ltd.)

Dipentaerythritol hexaacrylate (DPHA, manufactured by Aldrich Chemical Co., Inc.)
Catalyst

Dibutyltin dilaurate (manufactured by Wako Pure Chemical Industries, Ltd.)
Polymerization initiator

Irgacure 2959 (manufactured by BASF Corporation)
Additive

Polydimethylsiloxane (weight-average molecular weight: 770, manufactured by Alfa Aesar Co., Ltd.)

### Comparative Example 7

A film R-7 having a plated-layer precursor layer was produced in the same manner as in Comparative Example 1, except that a plated-layer precursor layer 1 and a plated-layer precursor layer 2, which are made of a plated layer forming composition, were directly formed on both surfaces of a PET film (trade name “A4300”, manufactured by Toyobo Co., Ltd.) without providing the undercoat 1 and the undercoat 2. Further, a film R2-7 having a patterned plated layer and an electroconductive film R3-7 were obtained in the same manner as in Comparative Example 1.

[Evaluation]

The following evaluations were carried out using each of films having a plated-layer precursor layer, films having a patterned plated layer, or electroconductive films of Examples and Comparative Examples obtained above.

(Evaluation of Hardness)

The hardness of the substrate on which the undercoat 1 was formed was evaluated.

Specifically, a spherical indenter having a tip radius of curvature of 0.2 mm was brought into contact with the surface of the undercoat 1 using a film hardness tester HM 500 manufactured by Fisher Instruments Co., Ltd. and a universal hardness (N/mm²) was measured under conditions of a maximum load of 2 mN and a loading time of 10 sec. The results are shown in Table 2.

(Evaluation of Friction Coefficient)

The friction coefficient of the substrate on which the undercoat 1 was formed was evaluated.

Specifically, first, CERAPHYL 38BKE (manufactured by Toray Industries, Inc.), which is a release paper, was placed without applying a force such that the release surface of the release paper was brought into contact with the surface of the undercoat 1. Next, the load applied in the case where a 100 g weight was placed thereon and the CERAPHYL was moved at a speed of 100 mm/min in the horizontal direction was measured using a force gauge FGX-2 (manufactured by Nidec-Shimpo Corporation). The friction coefficient was obtained by dividing the above measured value (load) by the weight of the weight. The results are shown in Table 2.

(Roll Handleability)

The case where a film having a plated-layer precursor layer can be produced by the above-mentioned roll-to-roll method of Comparative Example 1 was defined as “A”, and the case where a film having a plated-layer precursor layer cannot be produced by the above-mentioned roll-to-roll method of Comparative Example 1 was defined as “B”. The results are shown in Table 2.

(Evaluation of Alkali Resistance)

The produced film having a patterned plated layer was immersed in an aqueous sodium hydroxide solution at 30° C. and pH 13.5 for 15 minutes and the state of the patterned plated layer was observed under an optical microscope to evaluate alkali resistance. The alkali resistance was evaluated according to the following standards. The results are shown in Table 2.

“A”: The state of the patterned plated layer did not change.

“B”: No peeling of the patterned plated layer was observed, but the tint changed.

“C”: Peeling of the patterned plated layer was observed.

(Evaluation of Adhesiveness)

An adhesiveness test was carried out by sticking an adhesiveness test tape CT-24 (manufactured by Nichiban Co., Ltd.) to the patterned metal layer of the produced electroconductive film, sufficiently closely attaching the tape to the patterned metal layer, and then peeling off the test tape in one stroke. The adhesiveness was evaluated according to the following standards. The results are shown in Table 2.

“A”: No peeling of the metal layer was observed.

“B”: Peeling was observed in the range of less than 10% in the area of the pattern

“C”: Peeling was observed in the range of 10% or more in the area of the pattern

TABLE 2

| | | Film | | | | | | | |
|---|---|---|---|---|---|---|---|---|---|
| | Film having | having | | | | | | | |
| | plated-layer | patterned | | | Evaluation | | | | |
| | precursor | plated | Electroconductive | | Hardness | Friction | Roll | Alkali | |
| | layer | layer | film | Undercoat material | (N/mm²) | coefficient | handleability | resistance | Adhesiveness |
| Example 1 | T-1 | T2-1 | T3-1 | Undercoat material 1 | 4 | 0.53 | A | A | A |
| Example 2 | T-2 | T2-2 | T3-2 | Undercoat material 2 | 4.7 | 0.55 | A | A | A |
| Example 3 | T-3 | T2-3 | T3-3 | Undercoat material 3 | 2.7 | 0.61 | A | A | A |
| Example 4 | T-4 | T2-4 | T3-4 | Undercoat material 4 | 2.9 | 0.64 | A | A | A |
| Example 5 | T-5 | T2-5 | T3-5 | Undercoat material 5 | 3.5 | 0.55 | A | A | A |
| Example 6 | T-6 | T2-6 | T3-6 | Undercoat material 6 | 2.8 | 0.59 | A | A | A |
| Example 7 | T-7 | T2-7 | T3-7 | Undercoat material 7 | 3 | 0.69 | A | A | A |
| Comparative | R-1 | R2-1 | R3-1 | MT1007 | 73.2 | 0.17 | A | A | C |
| Example 1 | | | | (manufactured by | | | | | |
| | | | | NIPPONPAINT | | | | | |
| | | | | Co., Ltd.) | | | | | |
| Comparative | R-2 | R2-2 | R3-2 | HNBR | 1.5 | 5.4 | B | — | — |
| Example 2 | | | | (Zetpol 0020: | | | | | |
| | | | | manufactured by | | | | | |
| | | | | Zeon Corporation) | | | | | |
| Comparative | R-3 | R2-3 | R3-3 | Undercoat material 8 | 51.5 | 0.11 | A | A | C |
| Example 3 | | | | | | | | | |
| Comparative | R-4 | R2-4 | R3-4 | Undercoat material 9 | 17.2 | 0.13 | A | A | C |
| Example 4 | | | | | | | | | |
| Comparative | R-5 | R2-5 | R3-5 | Undercoat material 10 | 10.4 | 0.14 | A | A | B |
| Example 5 | | | | | | | | | |
| Comparative | R-6 | R2-6 | R3-6 | Undercoat material 11 | 13.3 | 0.11 | A | A | C |
| Example 6 | | | | | | | | | |
| Comparative | R-7 | R2-7 | R3-7 | — | — | 0.55 | A | C | C |
| Example 7 | | | | | | | | | |

It was confirmed that the film having a plated-layer precursor layer in each of Examples 1 to 7 exhibited excellent roll-to-roll productivity. In addition, it was confirmed that the patterned plated layer films of Examples 1 to 7 also exhibited excellent alkali resistance. Since the plating liquid such as a copper plating liquid is highly alkaline, excellent alkali resistance means excellent resistance to the plating liquid. It was further confirmed that the patterned metal layer of the electroconductive films of Examples 1 to 7 also exhibited excellent adhesiveness after plating, in other words, excellent adhesiveness between the metal layer and the substrate.

On the other hand, the films having a plated-layer precursor layer of Comparative Examples did not satisfy the desired performance.

(Driving as Touch Panel)

Electroconductive films in which the pattern shape of the metal layer of the electroconductive films T3-1 to T3-7 produced above was used as a wiring pattern for a touch panel were produced and whether or not the electroconductive film reacted as a touch panel was confirmed, and all reacted without any problem.

### EXPLANATION OF REFERENCES

10: film having a plated-layer precursor layer
50: film having a patterned plated layer
12: substrate
15: undercoat
20: patterned plated layer
22: metal layer
25: photo mask
30: plated-layer precursor layer
100: electroconductive film

What is claimed is:

1. A film having a plated-layer precursor layer, comprising:
a substrate;
an undercoat disposed on the substrate; and
a plated-layer precursor layer disposed on the undercoat,
wherein the undercoat has a hardness on the surface thereof of 10 N/mm² or less and a friction coefficient with release paper of 5 or less.

2. The film having a plated-layer precursor layer according to claim 1, wherein the plated-layer precursor layer contains a polymerization initiator and Compound X or Composition Y below.
Compound X: a compound having a functional group capable of interacting with a plating catalyst or a precursor thereof, and a polymerizable group
Composition Y: a composition containing a compound having a functional group capable of interacting with a plating catalyst or a precursor thereof, and a compound having a polymerizable group

3. A film having a patterned plated layer, comprising:
a substrate;
an undercoat disposed on the substrate; and
a patterned plated layer disposed on the undercoat,
wherein the undercoat has a hardness on the surface thereof of 10 N/mm² or less and a friction coefficient with release paper of 5 or less.

4. An electroconductive film comprising:
the film having a patterned plated layer according to claim 3; and
a metal layer disposed on the patterned plated layer in the film having a patterned plated layer.

5. An electroconductive film comprising:
the film having a patterned plated layer according to claim 3, and
a metal layer disposed on the patterned plated layer in the film having a patterned plated layer,
wherein the metal layer is formed by an electroless plating treatment.

6. A touch panel comprising:
the electroconductive film according to claim 4.

7. A touch panel comprising:
the electroconductive film according to claim 5.
